(19) United States
(12) Patent Application Publication
(10) Pub. No.: US 2004/0217785 A1
(43) Pub. Date: Nov. 4, 2004

(54) Reset circuits

(76) Inventors: Roger Peter Colbeck, Stittsville (CA); Ognjen Brkic, Ottawa (CA)

Correspondence Address: SMART & BIGGAR/FETHERSTONHAUGH & CO., P.O. BOX 2999, STATION D, 55 METCALFE STREET, OTTAWA, ON, K1P5Y6, CA

(21) Appl. No.: 10/428,106

(22) Filed: May 2, 2003

(51) Int. Cl. H03L 7/00

(52) U.S. Cl. 327/142

(57) ABSTRACT

A reset circuit produces a composite reset signal, in dependence upon a supply voltage, from reset signals produced by three reset units. A first unit produces its reset signal in dependence upon a precise voltage comparison. A second unit, operable at lower values of the supply voltage than the first unit, produces its reset signal in dependence upon the forward voltage drop of a diode. A third unit produces its reset signal in dependence upon charging of a capacitor from the supply voltage via a resistance, to maintain the composite reset signal for at least a predetermined period.

This invention relates to reset circuits. The invention is particularly concerned with a reset circuit for a power supply controller for controlling a plurality of power supplies, e.g. switch mode power supplies, DC power converters, or voltage regulators.

### REFERENCE TO RELATED APPLICATIONS

Reference is directed to the following copending United States Patent Application filed simultaneously herewith, the entire disclosure of which is hereby incorporated herein by reference:

“Power Supply Controller”, R. Orr et al., (79115-8, PP010).

### BACKGROUND

It is well known in electronic apparatus to provide a reset circuit which serves to hold parts of the apparatus in a reset state during an initial power-up process; accordingly this is generally referred to as a POR or power-on reset circuit. For example, the POR circuit may be arranged to maintain the reset state for at least a certain period sufficient to allow a supply voltage to reach an operating level and/or to become stable at such level, and/or to allow an oscillator to produce a stable clock signal which may be used in the apparatus.

Such a POR circuit may for example comprise a capacitor that is charged from the supply voltage via a resistor, a junction between the capacitor and the resistor being connected to a Schmitt trigger input of a circuit that provides a POR signal to maintain the reset state until the capacitor voltage exceeds a threshold level, this occurring after a time dependent on the time constant of the resistor-capacitor combination.

Such apparatus typically has a permitted supply voltage tolerance or range about a nominal supply voltage, for example a nominal supply voltage of 3.3 volts with a tolerance of ±10%, or a range of 2.97 to 3.63 volts, and may have other requirements for ramping of the supply voltage on power-up. Accordingly, the supplier of the apparatus assures proper operation of the apparatus for supply voltages complying with the specified parameters, but is not concerned with ensuring such compliance. Consequently, a simple POR circuit such as that described above can be considered to be sufficient.

The related application describes and claims a power supply controller which can be used for controlling a plurality of isolating power supplies, such as switch mode power supplies or DC power converters, for providing controlled electrical power to loads. For example, the power supplies may provide different supply voltages to various electrical circuits on a circuit card on which the power supply controller is also provided. The circuit card may be inserted into a card slot in an electronic equipment rack for providing signal connections and connections to a power supply voltage source.

In such a power supply controller, separate IC (integrated circuit) control units can be provided on the primary and secondary sides of a transformer that serves to maintain an electrical isolation barrier between input and output sides of the isolating power supplies. The transformer conveniently provides for signal coupling in both directions between the primary and secondary control units, and also for power transfer from its primary to its secondary side to supply operating power to the secondary control unit.

The primary side of the power supply controller can include a power supply, for example a switched mode power supply or DC converter, for providing a regulated supply voltage for the primary control unit from the source voltage which is also supplied to the isolating power supplies. Control circuits of this power supply can conveniently be incorporated into the primary control unit IC.

In such an arrangement, POR requirements are considerably more complex. Because the power supply controller is used to control power supplies for the electrical circuits, it is necessary for the power supply controller to be powered up and in a predetermined and operable state before the controlled power supplies can supply power to their electrical loads.

In addition, for the power transfer from the primary control unit to the secondary control unit as described above, the primary control unit can include driver circuits, with outputs coupled to the transformer, that can carry substantial currents. It is necessary for these outputs to be placed in a high impedance state, or tri-stated, before the supply voltage of the primary control unit reaches a low level at which such currents can begin to flow. Otherwise, large currents could flow which could damage the power supply controller and/or prevent its power-up.

Furthermore, the inclusion in the primary control unit IC of control circuits which are powered by the supply voltage of the primary control unit, and which are used to control the power supply which produces this supply voltage, creates a circular condition which further complicates the requirements for POR.

Accordingly, a need exists for an improved reset circuit, which in particular can be used in a power supply controller as discussed above.

### SUMMARY OF THE INVENTION

According to one aspect of this invention there is provided a reset circuit comprising: a first reset unit comprising a source of a reference voltage and a comparator for comparing a voltage dependent upon a supply voltage with a reference voltage to produce a first reset signal dependent upon the comparison; a second reset unit for producing a second reset signal in response to relative values of a threshold level of an input of a logic element, said threshold level being dependent upon the supply voltage, and a voltage drop of a component coupled to said input, said voltage drop being relatively less dependent upon the supply voltage than said threshold level; and a logic function for combining the first and second reset signals to produce a composite reset signal in dependence upon the supply voltage; the reference voltage source, comparator, logic element, and logic function being powered from the supply voltage.

Preferably said component comprises a forward biassed diode or diode-connected transistor.

The second reset unit can be operable at a lower value of the supply voltage than the first reset unit. This enables the composite reset signal to be derived, on power-up as the supply voltage rises from zero volts, initially from the second reset unit at small values of the supply voltage at which the first reset unit may not be operable, subsequently from both of the first and second reset units, and ultimately from the first reset unit in dependence upon an accurate voltage comparison.

The reset circuit preferably further comprises a third reset unit, including a capacitance arranged to be charged from the supply voltage via a resistance, for producing a third reset signal dependent upon a voltage to which the capacitance is charged, wherein the logic function is also responsive to the third reset signal to produce the composite reset signal. This enables the composite reset signal, on power-up, to be maintained for at least a predetermined period.

Another aspect of the invention provides a reset circuit comprising an element having an input and having an output for producing a reset signal dependent upon whether or not a voltage supplied to said input exceeds an input threshold level that varies in dependence upon a supply voltage of the element, and a component coupled to said input to provide thereto a voltage derived from the supply voltage and dependent upon a voltage drop that is relatively less dependent upon the supply voltage, so that as the supply voltage is increased from zero to an operating voltage the reset signal is produced from a relatively low value of the supply voltage to a value of the supply voltage less than the operating voltage.

Preferably the element comprises a buffer, for example an inverter, and the component comprises a diode or a diode-connected transistor which is forward biassed by a resistance coupled to the supply voltage, a forward voltage drop of the diode constituting an input voltage of the buffer.

This reset circuit preferably includes an arrangement for producing another reset signal, and a logic function for combining the reset signal produced by said element with said another reset signal to produce a composite reset signal. The arrangement for producing another reset signal can comprise a source of a reference voltage and a comparator for comparing a fraction of the supply voltage with the reference voltage to produce said another reset signal. Alternatively, or in addition, the arrangement for producing another reset signal can comprise a capacitance arranged to be charged from the supply voltage via a resistance, and a circuit for producing said another reset signal in dependence upon a voltage to which the capacitance is charged.

A further aspect of the invention provides a reset circuit for producing a reset signal for a circuit to be reset in dependence upon a supply voltage of the circuit, the reset circuit being powered by the supply voltage and comprising: a first reset unit comprising a source of a reference voltage and a comparator for comparing a fraction of the supply voltage with the reference voltage to produce a first reset signal dependent upon the comparison; a second reset unit comprising a diode coupled via a resistance to the supply voltage to be forward biassed, and a logic element having an input coupled to the diode and an output for producing a second reset signal in dependence upon whether or not a forward voltage drop of the diode exceeds an input threshold level of the logic element, said threshold level being dependent upon the supply voltage; and a logic function for combining the first and second reset signals to produce a composite reset signal for said circuit to be reset.

Preferably this reset circuit further comprises a third reset unit, including a capacitance arranged to be charged from the supply voltage via a resistance, for producing a third reset signal dependent upon a voltage to which the capacitance is charged, wherein the logic function is also responsive to the third reset signal to produce the composite reset signal.

### BRIEF DESCRIPTION OF THE DRAWINGS

The invention will be further understood from the following description by way of example with reference to the accompanying drawings, in which:

FIG. 1 shows a block diagram of a power supply controller;

FIG. 2 schematically illustrates a power supply of the power supply controller of FIG. 1;

FIG. 3 shows a block diagram of a reset circuit for the power supply controller of FIG. 1, in accordance with an embodiment of the invention;

FIG. 4 schematically illustrates a reset circuit for the power supply controller of FIG. 1, in accordance with an embodiment of the invention;

FIG. 5 is a graph illustrating dependence on a supply voltage of a reset signal voltage produced by the reset circuit of FIG. 4;

FIG. 6 is a graph illustrating operation of part of the reset circuit of FIG. 4; and

FIG. 7 illustrates a known form of diode-connected transistor.

### DETAILED DESCRIPTION

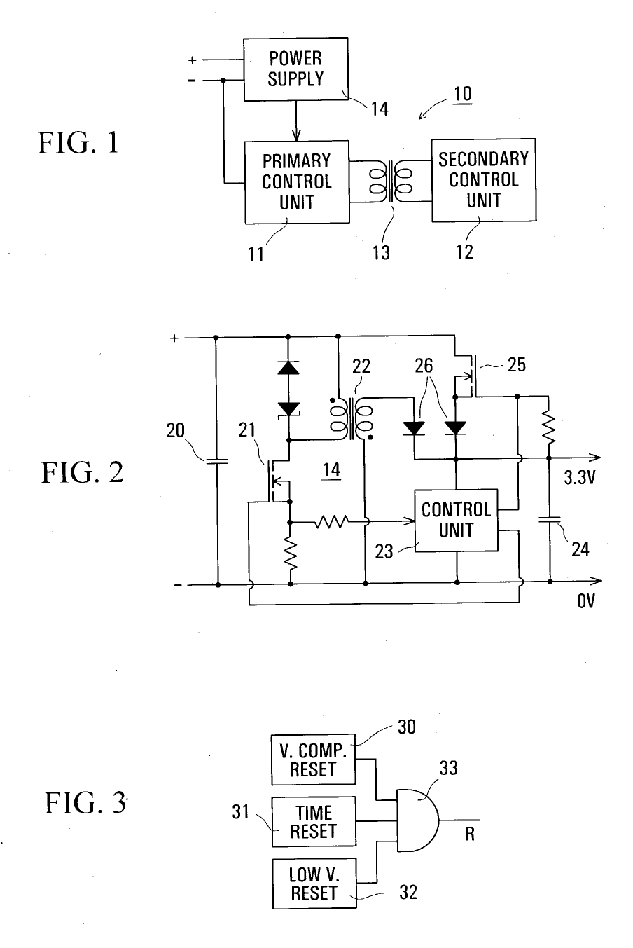

Referring to FIG. 1, a power supply controller 10 is illustrated for controlling a plurality of isolating power supplies (not shown) to which the power supply controller 10 is connected via ports of two control units 11 and 12, referred to respectively as primary and secondary control units. By way of example, the power supply controller 10 and the isolating power supplies that it controls may all be provided on a circuit card, which also includes electrical circuits constituting loads to be powered by the power supplies. In use, the circuit card is inserted in an equipment slot and thereby connected to a backplane which provides connections to a power source, for example a nominally 48 volt source via connections + and − in FIG. 1.

Via the ports of the control units 11 and 12, the power supply controller 10 can for example monitor the source voltage, monitor and adjust the output voltages of the controlled power supplies, and control sequencing of the power supplies via enable inputs of the power supplies. These functions generally require connections of the power supply controller 10 to both the primary and secondary sides of the isolating power supplies which it controls. In order to maintain electrical isolation between the primary and secondary sides, connections to the primary side are made from the primary control unit 11, connections to the secondary side are made from the secondary control unit 12, and the two control units communicate with one another by signals coupled in both directions via a transformer 13 between the control units 11 and 12.

As illustrated in FIG. 1, the power supply controller 10 also comprises a power supply 14. The source voltage is supplied to the power supply 14, which provides a supply voltage to the primary control unit 11. One form of the power supply 14 is described below, by way of example, with reference to FIG. 2.

The transformer 13 not only provides for signal coupling between the control units 11 and 12, but also serves to couple power in an isolated manner from the primary control unit 11 to the secondary control unit 12. To this end signal drivers in the primary control unit 11, having outputs coupled to the primary winding of the transformer 13, can have a high drive current capability, and the secondary control unit 12 can include a rectifier arrangement coupled to the secondary winding of the transformer 13 for deriving a supply voltage for the secondary control unit 12 from signals coupled from the primary control unit 11. The coupled power thus powers the secondary control unit 12 and any associated circuits on the secondary side of the power supply controller 10. Such associated circuits may for example include a non-volatile memory (not shown) that serves to store information for use in operation of the power supply controller 10.

All of the components 11 to 14 of the power supply controller 10 are desirably integrated into a single package, in which each of the control units 11 and 12 conveniently comprises an application-specific IC (ASIC).

The power supply 14 can for example be a current mode flyback power supply to provide sufficient power for the power supply controller 10, with a start-up circuit provided by a depletion mode MOSFET, for example providing a supply voltage of 3.3 volts to the primary control unit 11, as illustrated in FIG. 2.

Referring to FIG. 2, the current mode flyback power supply includes an input capacitor 20, a switching transistor 21, a transformer 22, a control unit 23, and an output capacitor 24. The start-up circuit comprises a depletion mode MOSFET 25, a supply voltage of 3.3 volts for the power supply control unit 23 and the primary control unit 11 being derived from either the start-up circuit or the flyback power supply via a respective one of two diodes 26. The control unit 23 has an output for controlling the switching transistor 21 in dependence on current in the source circuit of the transistor 21, and has another output for turning off the depletion mode transistor 25 when the flyback supply is operating.

Accordingly, the control unit 23 of the power supply 14 includes circuits, for example comparison and timing circuits, that are powered by the power supply 14 itself. Conveniently, the control unit 23 of the power supply can be incorporated into the integrated circuit constituting the primary control unit 11.

When a circuit card, containing the power supply controller 10 and power supplies controlled thereby, is inserted into an equipment slot and connects to a connector of a live backplane, the source voltage supplied to the terminals + and − in FIGS. 1 and 2 initially rises from zero volts as capacitors, such as the capacitor 20 of the power supply 14, charge. The power supply control unit 23 and the primary control unit 11 are supplied with the primary side supply voltage via the start-up depletion mode transistor 25 which provides a relatively low current, and the primary control unit 11 is initialized. As the input voltage continues to rise, the power supply control unit 23 controls the power supply 14 so that the primary side supply voltage is supplied by the higher power flyback supply. Subsequently power is coupled to the secondary control unit 12 via the transformer 13.

During an initial part of this power-up process, the supply voltage for the primary control unit 11 rises from zero volts (the capacitor 24 is discharged) to its nominal value of 3.3 volts as described here. As this supply voltage rises, it is necessary to hold parts of the primary control unit 11 in a reset state. For example, as the high current drivers of the primary control unit 11 may start to conduct (in an unknown starting state) at supply voltages of the order of one volt, it is necessary for a reset signal to be present, to ensure a high impedance state of the outputs of these drivers, by the instant at which the supply voltage reaches this level.

In addition, the reset signal must be maintained at least until the supply voltage has reached a desired value, for example of the order of 3.0 volts, and for a sufficient period to ensure that an oscillator of the primary control unit 11, from which a clock signal and timing for this control unit are derived, have reached a stable state. In this manner, the reset signal ensures that the primary control unit 11 is always powered up in a predetermined and desirable state.

In addition, the reset signal must be produced in the event that, at any time after power-up, the supply voltage for the primary control unit 11 falls below a threshold level established for normal operation of the primary control unit.

FIG. 3 shows a block diagram of a reset circuit, in accordance with an embodiment of this invention, for producing for the primary control unit 11 a reset signal R which can meet these requirements.

Referring to FIG. 3, the reset circuit comprises three reset sub-circuits or units 30, 31, and 32, each of which supplies a signal to a respective input of a 3-input AND gate 33, an output of which constitutes the reset signal R. The reset signal R is an active-low signal; consequently a reset state of the primary control unit 11 is maintained until the output signal of each of the units 30, 31, and 32, and hence the output of the AND gate 33, is high.

The reset sub-circuit or unit 30 provides at its output a voltage comparison (V. COMP.) reset signal by comparing a predetermined fraction of the supply voltage with a reference voltage, for example as further described below. This provides a monitoring of the supply voltage which can be precise for a supply voltage above about 2 volts but which, as explained further below, can be unreliable when the supply voltage is less than this.

The reset sub-circuit or unit 31 provides at its output a time constant (TIME) reset signal in a similar manner to that of a conventional resistor, capacitor, and Schmitt trigger input POR circuit as described above in the background of the invention. When the supply voltage rises rapidly, this time constant reset signal is maintained for a period (which is subject to considerable tolerances due to the characteristics of this type of POR circuit) sufficient to ensure that the oscillator reaches a stable oscillation state as described above. However, this time constant reset signal can not be relied upon if the supply voltage rises very slowly, because then the voltage to which the capacitor of the POR circuit is charged may closely track the slowly rising supply voltage.

The reset sub-circuit or unit 32 provides at its output a low voltage (LOW V.) reset signal which is designed to be effective when the supply voltage is at a low voltage, for example down to about 1 volt or less, but which need not be maintained at higher supply voltages, for example above about 2.5 volts, at which the other reset signals can be relied upon.

Consequently, the gating in the AND gate 33 of the reset signals produced by the units 30, 31, and 32 ensures that the reset signal R is produced in a reliable manner as the supply voltage rises from a low value to its nominal value, and thereafter in the event that the supply voltage falls below a precisely determined value, as is desired for proper operation of the primary control unit 11.

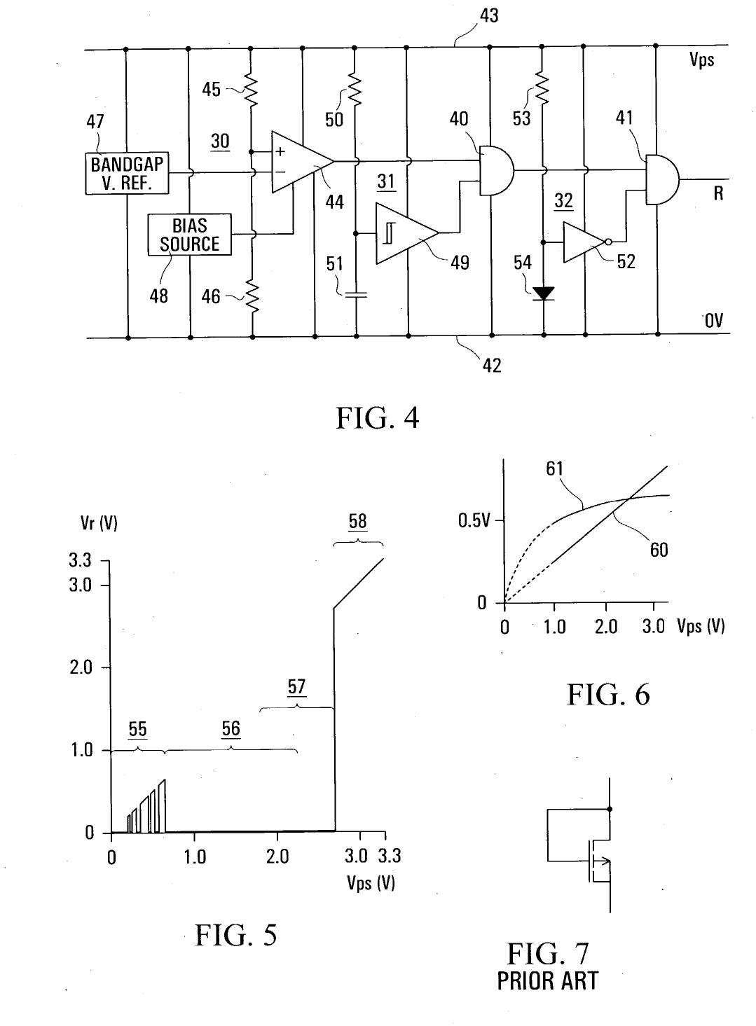

Further details of the reset sub-circuits or units 30, 31, and 32 and their operation as described above will be appreciated from the following description with reference to FIG. 4, which schematically illustrates a reset circuit, corresponding to the block diagram of FIG. 3, in accordance with an embodiment of the invention. In FIG. 4, the units 30, 31, and 32 are indicated generally by these same references, and the 3-input AND gate 33 of FIG. 3 is constituted by two 2-input AND gates 40 and 41, an output of the gate 40 being connected to one input of the gate 41, the active-low reset signal R being produced at the output of the gate 41.

In FIG. 4, the supply voltage for the primary control unit 11, produced by the power supply 14 as described above, appears between a zero volt line 42 and a line 43 at a positive supply voltage Vps, which is nominally 3.3 volts as described above, but which on power-up rises to this level from zero volts.

As illustrated in FIG. 4, the voltage comparison reset sub-circuit or unit 30 comprises a voltage comparator 44 which compares a fraction of the supply voltage Vps, produced by a potential divider formed by resistors 45 and 46 connected between the lines 42 and 43, supplied to its non-inverting (+) input with a reference voltage supplied to its inverting (−) input from a bandgap voltage reference 47. A bias current source provides a bias current for the comparator 44, an output of which provides the voltage comparison reset signal to one input of the AND gate 40. The comparator 44, bandgap voltage reference 47, and bias current source 48 are all connected to the lines 42 and 43 to receive the voltage Vps as a supply voltage.

As also illustrated in FIG. 4, the time constant reset sub-circuit or unit 31 comprises a Schmitt trigger input circuit 49 whose output is connected to the other input of the AND gate 40 to supply the time constant reset signal thereto. This unit 31 further includes a resistor 50 and a capacitor 51 connected in series between the lines 43 and 42 respectively, a junction between the resistor 50 and capacitor 51 being connected to the input of the circuit 49, which is also connected to the lines 42 and 43 to receive the voltage Vps as a supply voltage.

As further illustrated in FIG. 4, the low voltage reset sub-circuit or unit 32 comprises an inverter 52 whose output is connected to the second input of the AND gate 41 to supply the low voltage reset signal thereto. This unit 32 further includes a resistor 53 and a diode 54, poled to be forward biassed, connected in series between the lines 43 and 42 respectively, a junction between the resistor 53 and diode 54 being connected to the input of the inverter 52. The gates 40 and 41 and the inverter 52 are also all connected to the lines 42 and 43 to receive the voltage Vps as a supply voltage.

FIG. 5 is a graph illustrating an example of how a voltage Vr of the reset signal R, produced at the output of the gate 41 in FIG. 4, varies in dependence on the supply voltage Vps, as the supply voltage is increased from zero volts on power-up.

It can be appreciated that, on power-up, the supply voltage Vps initially rises from zero volts and must reach a certain value, for example of the order of 2 volts for a bandgap reference voltage of about 1.2 volts, before the bandgap voltage reference 47 and the bias current source 48 are operable and stable. Accordingly, the output of the comparator 44 is indeterminate or unknown for such initial low values of the supply voltage Vps. At very low values of the supply voltage Vps, for example less than one volt, the outputs of the circuit 49 and the inverter 52 are also indeterminate or unknown, so that the voltage of the reset signal R is unknown. FIG. 5 illustrates in a region 55 that the reset signal voltage Vr can vary between zero volts and the supply voltage Vps when the supply voltage is small.

As the supply voltage Vps increases towards, for example, about one volt, the diode 54 is forward biassed via the resistor 53 so that the input of the inverter 52 is at a positive voltage corresponding to the forward voltage drop of the diode 54 at the prevailing current passed by this diode. An input logic threshold level of the inverter 52 varies with (for example, it may be a substantially fixed fraction of) the supply voltage Vps, so that for small values of the supply voltage Vps the input of the inverter 52 exceeds this input threshold level. Consequently, the inverter 52 produces a zero voltage as the low voltage reset signal at its output, and via the AND gate 41 this produces a zero voltage of the reset signal R, regardless of the unknown states of the reset sub-circuits 30 and 31.

This occurs commencing at a low supply voltage Vps, for example at a voltage of about 0.65 volts as shown in FIG. 5. Thus the low voltage reset sub-circuit or unit 32 ensures that the reset signal is at zero volts, i.e. is active to hold the primary control unit 11 in a predetermined reset state, in a region 56 in FIG. 5.

With a continuing increase of the supply voltage Vps, the input logic threshold level of the inverter 52 rises to above the prevailing forward voltage drop of the diode 54, so that the output of the inverter 52 becomes high or equal to the supply voltage Vps. For example this can occur at a supply voltage Vps of about 2.5 volts, above a stable operating voltage for the reset sub-circuit 30. This corresponds to the higher voltage end of the region 56 in FIG. 5.

FIG. 6 is a graph illustrating this operation of the reset sub-circuit or unit 32. In FIG. 6, a line 60 represents a linear dependence of the input logic threshold level of the inverter 52 on the supply voltage Vps of the inverter, and a line 61 represents a non-linear dependence of the voltage drop of the diode 54 on the supply voltage Vps, this being relatively less dependent (i.e. the line 71 becoming more horizontal) as the supply voltage Vps increases, in accordance with the diode characteristics. Consequently, the lines cross in this case at a supply voltage Vps of about 2.5 volts, corresponding to the upper end of the region 56 in FIG. 5.

In a region 57 shown in FIG. 5, the supply voltage Vps is sufficient to ensure stable operation of the bandgap voltage reference 47 and the bias current source 48, so that the comparator 44 reliably compares the fraction of the supply voltage Vps supplied to its non-inverting input with the fixed and accurately determined bandgap reference voltage applied to its inverting input. In this region 57 the reference voltage is greater, so that the comparator 44 produces a zero voltage as the voltage comparison reset signal at its output, and via the AND gates 40 and 41 this maintains the zero voltage of the reset signal R. At its lower voltage end, the region 57 overlaps the higher voltage end of the region 56.

With continuing increase of the supply voltage Vps, the fraction of the supply voltage Vps supplied to the non-inverting input of the comparator 44 exceeds the reference voltage supplied to the inverting input of the comparator, and the output of the comparator 44 becomes high or equal to the supply voltage Vps. If, or when, the output of the circuit 49 is also high (i.e. if, or when, the capacitor 51 has charged, in accordance with its time constant with the resistor 50 and the supply voltage Vps, to a voltage that exceeds the threshold level of the Schmitt trigger input circuit 49), then the output of the AND gate 40 also becomes high, so that the reset signal R produced at the output of the AND gate 41 also becomes high as shown in a region 58 in FIG. 5. In this region 58 the voltage of the reset signal R continues to rise with the supply voltage Vps, up to the nominal 3.3 volts of the supply voltage Vps.

Subsequently, if the supply voltage Vps falls sufficiently for the comparator 44 to change state to produce a zero voltage output, via the AND gates 40 and 41 the active low state of the reset signal R is again produced to reset the primary control unit 11. The characteristics of the respective circuits are such that this low level of the reset signal is maintained for a sufficient period to reset the primary control unit 11 even for a temporary drop or glitch of the supply voltage Vps; alternatively this can be ensured by providing a pulse stretcher (not shown) of known form, for example at the output of the comparator 44 for increasing the duration of its zero voltage output.

From the above description it can be appreciated that the overlap of the regions 56 and 57 in FIG. 5 ensures that the reset sub-circuits or units 30, 31, and 32 cooperate so that the reset signal R is initially produced with its active-low state at a very low value of the supply voltage Vps, and so that this is maintained until the supply voltage is above a precise value determined by the bandgap reference voltage and for at least a predetermined time period determined by the time constant of the resistor 50 and capacitor 51.

Consequently, the reset circuit of FIG. 4 ensures that the primary control unit 11 of FIG. 1 is reliably reset on power-up, at a low initial supply voltage at which there is no significant current passed by its high current drivers, and despite the provision of the control unit 23 within the primary control unit 11.

By way of example, in one CMOS (complementary metal-oxide-semiconductor) form of the reset circuit of FIG. 5, with a nominal supply voltage of 3.3 volts and a bandgap reference voltage of about 1.2 volts, the resistors 45, 46, and 50 can have resistances of the order of 50 kΩ and can be formed as wells in the semiconductor structure, the capacitor 51 can be external to the semiconductor structure and can have a capacitance of the order of 50 nF to provide with the resistor 50 a desirable time constant, and the resistor 53 and diode 54 can be constituted by P-MOS and N-MOS transistors respectively. FIG. 7 illustrates an N-MOS transistor connected in known manner as a diode to constitute the diode 54. In addition, the comparator 44 can include hysteresis to accommodate small variations in the power supply voltage Vps in normal operation.

Although the above description refers to specific circuit arrangements, signal levels, logic functions, voltages, etc. of a particular form of the reset circuit, it can be appreciated that these are given only by way of example and that they all can be changed. For example, each of the reset sub-circuits or units 30, 31, and 32 could have any other desired form for providing the respective voltage comparison, time constant, and low voltage reset signals, and these reset signals can be combined in a logic function different from the AND gate 33 to produce a desired form of combined reset signal. Conceivably, for example, in the reset cub-circuit or unit 32 the positions of the resistor 53 and the diode 54 could be reversed, and the inverter 52 replaced by a non-inverting buffer, to provide a similar result.

In addition, although the above description relates to a reset circuit for the power supply controller 10 of FIG. 1, this need not be the case and reset circuits in accordance with other embodiments of the invention can be used to provide reset signals for any other circuits or purposes.

Furthermore, although as described above the reset circuit includes the three reset sub-circuits 30, 31, and 32, in other embodiments of the invention the time constant reset sub-circuit or unit 31 need not be present and can be omitted. This may in particular be the case if the circuit to be held in its reset state does not require at least a predetermined delay before it is released from the reset state; for example that circuit may have a rapid-starting (e.g. RC) oscillator instead of a resonator oscillator having a slower start-up. This may also be the case if the response speed of the reset circuit, including the sub-circuits 30 and 32, and/or the ramp-up of the supply voltage Vps, ensure that the reset signal is produced at least for any minimum period required by the circuit to be reset. To this end the sub-circuits 30 and/or 32 may include timing or delay components to stretch the duration of the reset signal; however, any such components desirably should not delay the response of the reset circuit to supply voltage glitches after the initial power-up process.

In addition, it is possible for the reset circuit to comprise only the reset sub-circuit or unit 32, without either of the other sub-circuits 30 and 31 and without the AND gate 33. Thus the reset circuit can comprise only the inverter 52 or another logic element (e.g. a gate, non-inverting buffer, Schmitt trigger input circuit, etc.) having an input whose logic threshold level varies with the supply voltage, the diode 54 or another component as discussed above providing a diode-like characteristic or relatively constant voltage drop as the supply voltage is increased, and the resistor 53 or a component providing an equivalent resistance, such as a P-MOS transistor as described above. In this case the upper voltage limit of the region 56 in FIG. 5, at which the supply voltage Vps is sufficient that the logic threshold level of the inverter 52 or other logic element, dependent upon this supply voltage, begins to exceed the voltage drop (also dependent on the supply voltage, but to a lesser extent) of the diode 54 or its equivalent, determines the point at which the reset signal ends as the supply voltage increases.

It can be further appreciated that although as described above the circuit 49 has a Schmitt trigger input, this providing a hysteresis to avoid glitches in the reset signal that it produces, this need not be the case. It can similarly be appreciated that other logic functions, for example the inverter 52, can if desired have a Schmitt trigger input. Further, it can be appreciated that the inverter 52 can be incorporated into the AND gate 41 as an inverting input thereof.

It will further be appreciated that the diode 54, instead of being a semiconductor diode or a diode-connected MOS transistor as described above with reference to FIG. 6, could be constituted by a diode-connected bipolar transistor, or could be replaced by any other component or circuit providing a diode-like characteristic, i.e. a voltage drop that is relatively constant as the supply voltage Vps increases.

Thus although particular embodiments of the invention are described above, it can be appreciated that numerous modifications, variations, and adaptations may be made without departing from the scope of the invention as defined in the claims.

1. A reset circuit comprising:
a first reset unit comprising a source of a reference voltage and a comparator for comparing a voltage dependent upon a supply voltage with a reference voltage to produce a first reset signal dependent upon the comparison;
a second reset unit for producing a second reset signal in response to relative values of a threshold level of an input of a logic element, said threshold level being dependent upon the supply voltage, and a voltage drop of a component coupled to said input, said voltage drop being relatively less dependent upon the supply voltage than said threshold level; and
a logic function for combining the first and second reset signals to produce a composite reset signal in dependence upon the supply voltage;
the reference voltage source, comparator, logic element, and logic function being powered from the supply voltage.

2. A reset circuit as claimed in claim 1 wherein said component comprises a forward biassed diode or diode-connected transistor.

3. A reset circuit as claimed in claim 1 wherein the logic element comprises a buffer and said component comprises a diode or a diode-connected transistor which is forward biassed by a resistance coupled to the supply voltage, a forward voltage drop of the diode constituting an input voltage of the buffer.

4. A reset circuit as claimed in claim 3 wherein the buffer comprises an inverter.

5. A reset circuit as claimed in claim 1 and further comprising a third reset unit, including a capacitance arranged to be charged from the supply voltage via a resistance, for producing a third reset signal dependent upon a voltage to which the capacitance is charged, wherein the logic function is also responsive to the third reset signal to produce the composite reset signal.

6. A reset circuit as claimed in claim 5 wherein the third reset unit comprises a Schmitt trigger input circuit powered from the supply voltage.

7. A reset circuit as claimed in claim 1 wherein the second reset unit is operable at a lower value of the supply voltage than the first reset unit.

8. A reset circuit comprising an element having an input and having an output for producing a reset signal dependent upon whether or not a voltage supplied to said input exceeds an input threshold level that varies in dependence upon a supply voltage of the element, and a component coupled to said input to provide thereto a voltage derived from the supply voltage and dependent upon a voltage drop that is relatively less dependent upon the supply voltage, so that as the supply voltage is increased from zero to an operating voltage the reset signal is produced from a relatively low value of the supply voltage to a value of the supply voltage less than the operating voltage.

9. A reset circuit as claimed in claim 8 wherein the component comprises a forward biassed diode or diode-connected transistor.

10. A reset circuit as claimed in claim 8 wherein the element comprises a buffer and the component comprises a diode or a diode-connected transistor which is forward biassed by a resistance coupled to the supply voltage, a forward voltage drop of the diode constituting an input voltage of the buffer.

11. A reset circuit as claimed in claim 10 wherein the buffer comprises an inverter.

12. A reset circuit as claimed in claim 8 and including an arrangement for producing another reset signal, and a logic function for combining the reset signal produced by said element with said another reset signal to produce a composite reset signal.

13. A reset circuit as claimed in claim 12 wherein the arrangement for producing another reset signal comprises a source of a reference voltage and a comparator for comparing a fraction of the supply voltage with the reference voltage to produce said another reset signal.

14. A reset circuit as claimed in claim 12 wherein the arrangement for producing another reset signal comprises a capacitance arranged to be charged from the supply voltage via a resistance, and a circuit for producing said another reset signal in dependence upon a voltage to which the capacitance is charged.

15. A reset circuit for producing a reset signal for a circuit to be reset in dependence upon a supply voltage of the circuit, the reset circuit being powered by the supply voltage and comprising:
a first reset unit comprising a source of a reference voltage and a comparator for comparing a fraction of the supply voltage with the reference voltage to produce a first reset signal dependent upon the comparison;
a second reset unit comprising a diode coupled via a resistance to the supply voltage to be forward biassed, and a logic element having an input coupled to the diode and an output for producing a second reset signal in dependence upon whether or not a forward voltage drop of the diode exceeds an input threshold level of the logic element, said threshold level being dependent upon the supply voltage; and
a logic function for combining the first and second reset signals to produce a composite reset signal for said circuit to be reset.

16. A reset circuit as claimed in claim 15 wherein the diode is constituted by a diode-connected transistor.

17. A reset circuit as claimed in claim 15 wherein the logic element comprises an inverter.

18. A reset circuit as claimed in claim 15 and further comprising a third reset unit, including a capacitance arranged to be charged from the supply voltage via a resistance, for producing a third reset signal dependent upon a voltage to which the capacitance is charged, wherein the logic function is also responsive to the third reset signal to produce the composite reset signal.
